(19) United States
(12) Patent Application Publication
(10) Pub. No.: US 2010/0000856 A1
(43) Pub. Date: Jan. 7, 2010

(54) METHOD AND DEVICE FOR THE COLD-PLASMA DEPOSITION OF A BARRIER LAYER AND MACHINE USING SUCH A DEVICE

(75) Inventors: Nicolas Chomel, Octeville-Sur-Mer (FR); Naima Boutroy, Octeville-Sur-Mer (FR); Ertan Cetinel, Octeville-Sur-Mer (FR)

Correspondence Address: SUGHRUE MION, PLLC, 2100 PENNSYLVANIA AVENUE, N.W., SUITE 800, WASHINGTON, DC, 20037, US

(73) Assignee: SIDEL PARTICIPATIONS, Octerville-Sur-Mer (FR)

(21) Appl. No.: 12/376,539

(22) PCT Filed: Aug. 2, 2007
(86) PCT No.: PCT/FR2007/051768

§ 371 Date: Feb. 5, 2009

(30) Foreign Application Priority Data
Aug. 7, 2006 (FR) 0653304

(51) Int. Cl. C23C 14/35

(52) U.S. Cl. 204/192.13; 204/298.03

(57) ABSTRACT

Method for controlling a high-voltage power supply generator for a magnetron (16) for producing a cold plasma inside a hollow body in order to carry out the deposition of a boundary layer within said hollow body, characterised in that it comprises selecting (E2) a generator operation mode from a plurality of operation modes (MODE 1, MODE 2, MODE 3), modifying the operation mode (MODE 1, MODE 2, MODE 3) of the generator by varying at least one coefficient ((a, b, c); (a1, b1, c1)) defining a maximal power Pₘₐₓ of the waveform of the supply power of the magnetron (16) according to a set average power P_{moy} of the magnetron (16), the magnetron (16) supply waveform being repeated recurrently with a cyclic conduction ratio Th depending on the set average power P_{moy} and/or on the maximal power Pₘₐₓ.

### FIELD OF THE INVENTION

The present invention relates to a method and a device for controlling a high-voltage power supply generator for a magnetron for the cold-plasma deposition of a barrier layer. It also relates to a machine for cold-plasma deposition of a barrier layer using such a device.

### BACKGROUND OF THE INVENTION

In the prior art, methods have already been described which, after the injection of precursor gases, or even gas mixtures, for example based on carbon and/or silicon, into a hollow body made from plastic such as PET, are suitable for producing a cold plasma leading to the formation of barrier layers. These layers are particularly suitable when the hollow bodies are containers: this is because they allow the contents, subsequently filled in the container, to be protected from gas exchanges with the exterior, particularly with oxygen in the air. Such a protection is particularly advantageous, for example, but not exclusively, when the product filled in the container is a food.

In the prior art, such methods are implemented using machines for the cold-plasma deposition of a barrier layer comprising at least one treatment station with a cavity and a magnetron generating microwaves. At least one hollow body to be treated is introduced into the cavity and the microwave power, which is applied at a convenient location in the inner volume of the hollow body containing precursor gas previously injected, generates a cold plasma of which the active species are projected against the wall of the hollow body. The whole of these active species forms the barrier deposit against gas exchanges between the interior and the exterior of the hollow body.

However, the prior art devices for generating the electric power supply of the magnetron, which convert the electric power they receive to a microwave power which they radiate, do not have optimized performance for such a deposition of an internal barrier layer.

To obtain high production rates, it is known that the barrier layer deposition machines comprise a plurality of workstations (up to 48 on hitherto known machines) each comprising at least one magnetron or one radiant antenna connected to a magnetron. This has the result that the failure of a single one of these magnetrons causes production losses. Furthermore, a poor definition of the electric power supply of the magnetron (power waveform) limits the performance of the process and the service life of this magnetron.

### SUMMARY OF THE INVENTION

The present invention provides a remedy to these drawbacks of the prior art, in that it relates to a method for controlling a high-voltage power supply generator for a magnetron for producing a cold plasma inside a hollow body in order that a barrier layer becomes deposited within the hollow body.

According to a first of its aspects, the present invention relates to a method for controlling a high-voltage power supply generator for a magnetron for producing a cold plasma inside a hollow body in order to carry out the deposition of a barrier layer within said hollow body, characterized in that it consists in selecting a generator operating mode from a plurality of operating modes, a modification of the operating mode of the generator varying at least one coefficient defining a maximum power Pₘₐₓ of the waveform of the supply power of the magnetron according to an average power setpoint P_{avg} of the magnetron, the magnetron supply waveform being repeated recurrently with a cyclic conduction ratio Th depending on the average power setpoint P_{avg} and/or the maximum power Pₘₐₓ.

Advantageously, the maximum power Pₘₐₓ of the waveform is predetermined according to the power setpoint P_{avg}.

According to a first embodiment of an operating mode of the method according to the invention, said relation between the average power P_{avg} and the maximum power Pₘₐₓ has the polynomial form

Pₘₐₓ=a*(P_{avg})ⁿ+b*(P_{avg})ⁿ⁻¹+c*(P_{avg})ⁿ⁻²+ . . . +k*(P_{avg})^{n-p},

where n and p are whole numbers, n being higher than or equal to p, and (a, b, c, . . . k) being variable coefficients.

Advantageously, said polynomial equation has a parabolic form Pₘₐₓ=a*(P_{avg})²+b*P_{avg}+c where a, b, c are variable coefficients.

Preferably, the cyclic conduction ratio Th, in percent, is determined by the relation

Th=100*P_{avg}*π/(2*Pₘₐₓ).

According to a second embodiment of an operating mode of the method according to the invention, the cyclic conduction ratio Th, in percent, is dependent on the average power setpoint P_{avg} via the polynomial equation having the formula

Th=a1*(P_{avg})ⁿ+b1*(P_{avg})ⁿ⁻¹+c1*(P_{avg})ⁿ⁻²+ . . . +k1*(P_{avg})^{n-p}

where n and p are whole numbers, n being higher than or equal to p, and (a1, b1, c1, . . . k1) being variable coefficients.

Advantageously, said polynomial relation has a parabolic form Th=a1(P_{avg})²+b1*P_{avg}+c1, where a1, b1, c1 are variable coefficients.

Preferably, the maximum power Pₘₐₓ is determined by the relation Pₘₐₓ=π*P_{avg}/(2*Th).

Advantageously, in one operating mode, none of the coefficients is zero.

Alternatively, in another operating mode, at least two coefficients are zero.

More precisely, in one operating mode, the maximum power Pₘₐₓ is fixed constant.

Similarly, the cyclic ratio Th is linearly dependent on the average power P_{avg}.

Advantageously, the maximum power is determined and adapted for varying on the basis of a safe area bounded by a maximum permissible value of the maximum power P_{max,max} for the magnetron and a lower value of the maximum power P_{max,min} determined by a maximum cyclic conduction ratio Thₘₐₓ given by the design of the magnetron and of the power supply thereof.

Advantageously, in one further operating mode, the maximum power Pₘₐₓ is linearly dependent on the value of the average power setpoint P_{avg}.

In still another operating mode, the cyclic conduction ratio Th is fixed.

Still in the same other operating mode, the cyclic conduction ratio Th of the waveform is determined and selectable on the basis of a safe area bounded by a value of the maximum permissible cyclic conduction ratio Thₘₐₓ and a lower value of the minimum cyclic conduction ratio Thₘᵢₙ determined in relation with the upper limit of the maximum permissible power P_{max,max} which depends on the characteristics of the magnetron and of the power supply thereof.

Advantageously, said coefficients are determined by tests of treatment of a batch of hollow bodies from which a relation is derived between the average power setpoint P_{avg}, the maximum power Pₘₐₓ and the cyclic conduction ratio Th.

Advantageously, the coefficient a is between (−0.0020) and 0.0020, the coefficient b is between 0 and 4, and the coefficient c is between 0 and 3000.

According to a second of its aspects, the present invention relates to a device for controlling a high-voltage power supply generator for magnetron for the cold-plasma deposition of a barrier layer of the invention, of the type comprising:

a circuit for controlling a high-voltage power supply generator;

a circuit for controlling the control electrodes of a power switch bridge in relation with a power waveform setpoint, said control device using the method as described above and comprising:

means for storing parameters of maximum power, of conduction in relation with a predefined operating mode,

means for selecting an average power setpoint P_{avg},

means for determining an operating frequency,

means for selecting an operating mode for the generator, and

means for determining all the instantaneous setpoint characteristics defining the power wave for a work target expressed in terms of performance of the deposit created on the hollow body and the respect of integrity thereof while controlling the temperature rise thereof during the deposition.

According to a third of its aspects, the present invention relates to a machine for depositing a barrier layer on the inside wall of a plastic hollow body, such as a bottle, using a cold plasma excited by a magnetron, supplied by a high-voltage generator, controlled by a control device as mentioned above.

### BRIEF DESCRIPTION OF THE DRAWINGS

Other features and advantageous of the present invention will be more clearly understood from the description of an example exclusively illustrative and nonlimiting of the scope of the invention, and in conjunction with the appended figures in which:

FIG. 1 is a schematic representation in three parts, respectively 1a, 1b, 1c, to illustrate a device for controlling a high-voltage electric power supply generator for supplying a magnetron for a cold-plasma barrier layer deposition machine, the cold plasma being excited by the microwave radiation of the powered magnetron;

FIG. 2 shows two examples of instantaneous power waves;

FIG. 3 shows a flowchart of one embodiment of the method according to the invention;

FIGS. 4a and 4b show two functions respectively illustrating the variation of the maximum power Pₘₐₓ in relation with the average power P_{avg} and the variation of the cyclic conduction ratio Th in relation with the average power P_{avg}, for determining the electric power supply of the magnetron according to two alternatives of a first operating mode of the electric power supply generator according to the invention (MODE 1);

FIG. 5 shows a safe area, in which the maximum Pₘₐₓ of the magnetron power supply waveform may vary, as a function of the average power useful for determining the electric power supply of the magnetron in a second operating mode of the electric power supply generator according to the invention (MODE 2);

FIG. 6 shows a safe area, in which the cyclic conduction ratio Th of the magnetron power supply waveform can be selected, as a function of the average power serving to determine a magnetron electric power supply waveform in a third operating mode of the electric power supply generator according to the invention (MODE 3);

FIG. 7 shows a circuit for switching between a plurality of operating modes of the electric power supply generator for determining the characteristics of the magnetron power wave;

FIG. 8 is a schematic representation of a waveform obtained with the first generator operating mode;

FIG. 9 is a schematic representation of a waveform obtained with the second generator operating mode;

FIG. 10 is a schematic representation of a waveform obtained with the third generator operating mode.

### DETAILED DESCRIPTION OF THE INVENTION

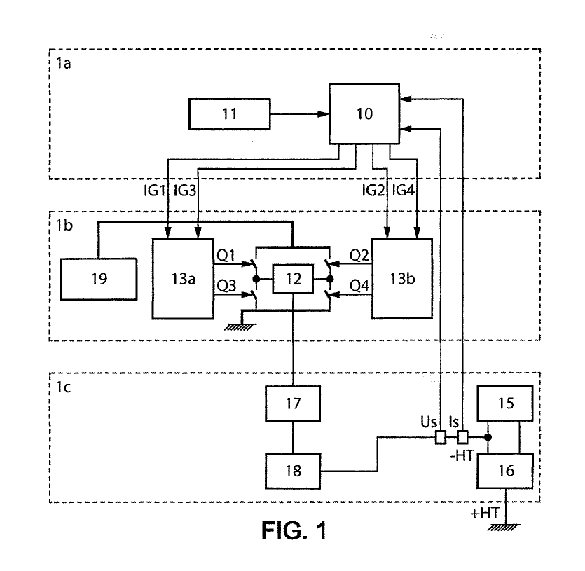

FIG. 1 schematically shows a device for controlling the supply of a high-voltage electric power supply generator for a magnetron, said control device of the invention comprising:

in a first part 1a: a member for treating and controlling a device for controlling a high-voltage power supply generator for magnetron;
in a second part 1b: the power converter portion; and

in a third part 1c: the high-voltage part of the power supply and of the current and voltage measurements of the magnetron 16.

The control device of the invention comprises a treatment member 1a shown in part 1a constructed around a microcontroller 10 which receives at least two measurement signals and one setpoint signal, that is:

a current Is measurement signal, the image of the current supplying the anode of the magnetron 16, delivered by the part 1c, the magnetron 16, and more precisely the filament thereof, being powered by a transformer 15;

a voltage Us measurement signal, the image of the power supply voltage between the anode of the magnetron 16 between the power supply from the circuit 1c and mass;

a setpoint signal P_{avg} (average power setpoint) supplied by a member 11 for determining the power setpoint.

The control device of the invention is implemented in the form of a program recorded in the memory of the microcontroller 10, one embodiment of the control method according to the invention adapted to the high-voltage power supply generator for magnetron 16 being described in greater detail below. The recorded program, when run in particular by the “DSP” circuit of the microcontroller 10 of the control device comprising the parts 1a to 1c, periodically detects the average setpoint P_{avg} supplied by the member 11 as well as the values of the current Is and voltage Us measurements and determines four control signals, respectively IG1 to IG4 sent to two circuits 13a and 13b for controlling power switches Q1 to Q4 which modulate the energy supplied by the power supply 19 using the PWM (Pulse Width Modulation) technology. The power transfer is provided by the circuit 12 which consists of a resonance filter. The modulation, controlled by the circuits 13a and 13b, is carried out by power switches Q1 to Q4 capable of switching high power levels in high frequency. The primary part of the high-voltage transformer is incorporated in the resonant circuit 12.

It is already known in the prior art to provide devices for depositing a barrier layer on plastic hollow bodies using a cold plasma excited and maintained by means of a magnetron producing microwave radiation when a suitable precursor gas (single gas or gas mixture) has been introduced into the plastic hollow body. The magnetron must be connected to a high-voltage generator. In order to convert the A.C. voltage produced in the part 1b (that is the resonance converter part) to an A.C. high voltage, it is known to use a high-voltage step-up transformer 17 of which the primary circuit integrated in the filter 12 is connected in the current branch located between the four power switches Q1 to Q4, and of which the secondary is connected to a high-voltage rectifier bridge 18, consisting for example of four diodes mounted in a manner known (such as a Graetz bridge). Moreover, to carry out a filtering so as to adjust the maximum values of the high-voltage wave delivered at the output of the rectifier bridge 18, it is known to use magnetic-core coils (not shown) for filtering the current at the terminals of the magnetron 16.

Downstream of the filtering, the magnetron 16 is connected via the “negative high voltage”−HT and “positive high voltage”+HT connections, used to connect the “high voltage” mass electrodes and the “high voltage” filament. A third filament heating connection is also provided, and the “negative high voltage”−HT power supply as well as the filament heating voltage are supplied by a power supply transformer 15 adapted to the magnetron 16. The “positive high voltage”+HT terminal is connected to the high voltage mass of the inventive device.

In a by-pass between the two “negative high voltage” and the “positive high voltage” terminals of the high-voltage power supply generator, a circuit for measuring the instantaneous voltage is provided which the “negative high voltage” potential Us, the image of the supply voltage between the anode of the magnetron and the mass thereof, with which the magnetron 16 is supplied to be measured and of which the instantaneous measurement allows to represent the radiant microwave energy that is applied in order to excite the molecular species in the gas and to maintain the cold plasma, generating the barrier layer.

Furthermore, the measurement of the current Is, the image of the current supplying the anode of the magnetron 16, delivered by the resonance converter part 1b, is carried out at the output of the high voltage rectifier bridge 18.

As a result, the precise control of the current delivered by the resonance converter part 1b as well as the voltage applied to the magnetron 16 thereby allows to produce a representation of the instantaneous power consumption of the magnetron 16. Thanks to a predefined relation of the conversion of electric power to microwave power provided by the magnetron 16, it is possible to control the state of the cold plasma generated in the introduced precursor gas.

In a prior step, during numerous tests, a determination—is carried out of the optimal characteristics of the power wave (form, frequency, peak value) to be applied to the magnetron 16 in order to produce a satisfactory barrier layer without excessively heating the plastic hollow body. In fact, it is indispensable to generate a barrier layer with precise characteristics while controlling the temperature rise of the plastic wall of the hollow body, so as to avoid deforming or altering the appearance thereof. It results in that it is thanks to the control of the characteristics defining the wave aas well as of the pressures under which the gas mixture is distributed into the hollow body that a proper barrier layer is thereby produced. To make the production of a high-voltage power supply wave of the magnetron readier and better controllable in order to obtain hollow bodies correctly coated with a homogeneous barrier layer, without said bodies being subjected to an excessively high temperature of the cold plasma, and in order for the deposit to have a layer with the desired barrier properties, related in particular to the homogeneity and the thickness thereof, the invention proposes a method for generating a power wave controlled according to a plurality of operating modes, whereby it is possible to readily change a mode for generating a power supply waveform of the magnetron in relation with the characteristics of the hollow body and of the injected gas, and to select an optimal operating mode of the generator in relation with several characteristics of a generic magnetron supply waveform.

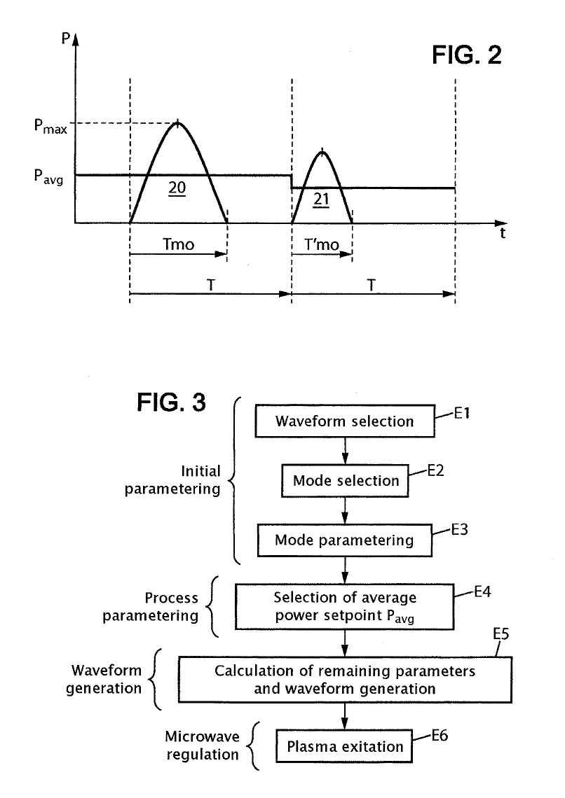

FIG. 2 shows a timing diagram of a succession of two waveforms 20 and 21 in a particular embodiment of the invention. The time is plotted on the x-axis and the instantaneous power P on the y-axis. According to the inventive method, it is possible to parameterize the maximum amplitude characteristics, that is the maximum supply power Pₘₐₓ having active duration Tmo, recurrence period T connected by the cyclic conduction ratio Th=Tmo/T, of a waveform having the shape of a positive sinusoid arch. It is obvious that other waveforms are also concerned by the inventive method, for example a waveform of the triangular peak type or of the crest type.

In general, the cyclic conduction ratio Th is defined by the ratio Th=Tmo/T, where Tmo is the active time of the elementary wave, and T the recurrence period. The average of the power P_{avg} is then defined over the period T. It is obtained by calculating the average power from 0 to T

$$Pavg = \frac{1}{T} {\int }_{0}^{T} P ( t ) d t ,$$

which in the case of a wave in the form of a sinusoid arch leads to:

$$Pavg = \frac{2 \cdot P max \cdot Th}{π}$$

The method according to the invention allows to select the waveform, the cyclic conduction ratio Th thereof, as well as the percentage of modification thereof (in other words the homothetic transformation thereof) from one recurrence to another so as to adapt to objectives of treatment by barrier layer deposition defined in terms of coloration of the hollow body treated, temperature of the hollow body during the application of the microwave plasma, and in terms of uniformity of the barrier layer, the uniformity being expressed in particular in terms of thickness of deposit.

FIG. 2 thus shows the variation over time t of the supply power P of the magnetron, thereby forming two examples of sinusoid arch waves and with a homothetic decrease of the wave from a first waveform 20 to the first recurrence of the wave 21 for a new power setpoint, the active duration Tmo being reduced accordingly to T′mo, while the period T remains constant.

In particular, the invention sets a predefined condition between the average power setpoint P_{avg}, the maximum power Pₘₐₓ and the cyclic conduction or repetition ratio Th of the waveform. For example, in the case in which the waveform is fixed during a sufficiently long period in a sinusoid arch waveform, such a predefined condition can be expressed by an equation having the form: P_{avg}=(2*Pₘₐₓ*Th)/π where “π” refers to the angular units.

In the exemplary embodiment in FIG. 2, a first sinusoid arch 20 has an active duration, Tmo, which is a first portion of a waveform repetition period T. To completely determine this wave intended for supplying the magnetron 16, the maximum value of the instantaneous power envelope must also be determined. To control the energy applied to the microwave plasma by the magnetron 16, means are therefore available in particular for adjusting the maximum power Pₘₐₓ and the duration of the first portion constituting the active duration, Tmo, of application of the microwaves by the waveform over the complete recurrence period T of the waveform.

So as to control the operation of the high-voltage power supply generator of the magnetron 16, an operating mode is determined in which an average power setpoint is assumed, which will be denoted in the following description by P_{avg}, it being understood that the control device of the invention, according to the selected operating mode, comprises means for determining:

the actual waveform, preferably as a sinusoid arch waveform,

the parameters determining the wave, like the cyclic conduction ratio Th of the microwaves with respect to the waveform recurrence period T, and the maximum power Pₘₐₓ. The wave is defined by the shape thereof (preferably a positive sinusoid half-arch), the natural period thereof and the recurrence period thereof connected by the conduction ratio Th, and the maximum power Pₘₐₓ.

In other words, the present invention proposes a method for controlling a high-voltage electric power supply generator for magnetron 16 for producing a cold plasma inside a hollow body in order to deposit a barrier layer inside said hollow body, characterized in that it consists in selecting a generator operating mode from a plurality of operating modes, the modification of the generator operating mode causing the variation of at least one coefficient defining a maximum power Pₘₐₓ of the waveform of the supplied power of the magnetron 16 in relation with an average power setpoint P_{avg} of the magnetron 16, the waveform supplying the magnetron 16 being repeated with a recurrence having a period T.

FIG. 3 shows a flowchart of the method according to the invention. During step E1, the actual power waveform is selected, preferably a sinusoid arch form. During step E2, an operating mode is selected from a plurality of predefined modes. According to the mode selected, in step E3, it may be necessary to enter the value of a parameter (Pₘₐₓ or Th) and check that the value of this parameter is compatible with the P_{avg} setpoint range intended for use for the application. The method for calculating the limits is defined later (operating range). Before starting the treatment of the hollow bodies, a process is defined in step E4 enabling the operator to acquire the average power setpoint P_{avg}. The control device comprising a microcontroller 10 runs a sequence (for example a computer program) including an algorithm for computing the parameter of the maximum power Pₘₐₓ and/or the parameter of the cyclic conduction ratio Th, if necessary, during step E5. The wave satisfying the average power setpoint is then defined. In one embodiment, the microcontroller 10 also comprises means for determining the instantaneous power setpoint allowing the regulation of the power supply of the magnetron 16. Finally, during step E6, the supply device of the magnetron 16 controlled by the block 1a generates and regulates according to the wave defined by the prior steps E1 to E5.

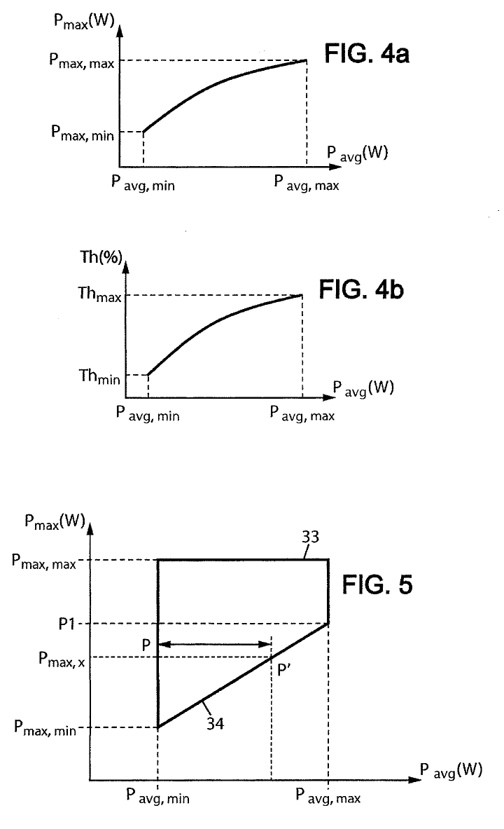

FIG. 4a shows the variation in the value of the maximum power Pₘₐₓ of the supply wave of the magnetron 16 as a function of the average power setpoint P_{avg} of the magnetron 16 (in other words, the power consumption of the magnetron 16).

During numerous tests, using magnetrons with a capacity lower than 1 kW and operating with a rated frequency of about 2.45 GHz and a sinusoidal waveform, it was determined that for a rated frequency, the maximum power Pₘₐₓ is correctly represented by a section of parabola determined by an equation like:

Pₘₐₓ=a*(P_{avg})²+b*P_{avg}+C

where the constants a, b and c are determined from tests performed on a significant range of hollow bodies used in the barrier layer deposition machines of the invention.

More generally, it has been found that the equation between the average power P_{avg} and the maximum power Pₘₐₓ has a polynomial form

Pₘₐₓ=a*(P_{avg})ⁿ+b*(P_{avg})ⁿ⁻¹+c*(P_{avg})ⁿ⁻²+ . . . +k*(P_{avg})^{n-p},

where n and p are whole numbers, n being higher than or equal to p, and (a, b, c, . . . , k) being variable coefficients, it being understood that the preferential form of the equation is a parabolic form.

FIG. 4a thus shows a section of a parabolic curve between two limit operating points of the generator according to a first operating mode between a point where the average power P_{avg,min} is a minimum and where the maximum power has a lower bound value P_{max,min} and a point where the average power is a maximum P_{avg,max} and where the maximum power has an upper bound value P_{max,max}.

It has already been shown that the cyclic conduction ratio could be given by the following equation, Th(%)=100*P_{avg}*π/(2*Pₘₐₓ) for a sinusoidal waveform. In general, the cyclic conduction ratio may be given by a formula of the type Th=F(P_{avg}).

Thus, having the two characteristic curves Pₘₐₓ=f(P_{avg}) and Th=F(P_{avg}), it suffices for the user to define the desired setpoint value P_{avg}. In a particular embodiment, the microcontroller also comprises means for determining the values Pₘₐₓ and Th automatically, knowing the other indispensable parameters (frequencies, etc.), on the basis of a map storage incorporating the abovementioned two curves, varied according to said indispensable parameters. The characteristics of the sinusoidal arch wave to be used during the regulation of the microwaves (supply of the magnetron) are thereby accurately calculated.

These two characteristic curves f(P_{avg}) and F(P_{avg}) allow, in combination, to establish a first operating mode for obtaining the objectives described above for the hollow body and the barrier layer thereof deposited by cold plasma.

Alternatively, when the cyclic conduction ratio Th is not modeled by the equation having the formula Th(%)=100*(P_{avg})*π/(2*Pₘₐₓ) (that is when the waveform is not of a sinusoidal type), it is also possible to model the variation of the cyclic conduction ratio Th in relation with the average power P_{avg}.

To do this, during numerous tests, using magnetrons with a capacity lower than 1 kW and operating at a rated frequency of about 2.45 GHz, it was determined that the cyclic ratio Th could also be modeled by a section of parabola determined by an equation like Th=a1*P_{avg}²+b1*P_{avg}+c1 limited by the coordinate points (P_{avg,min}; Thₘᵢₙ) and (P_{avg/max}; Thₘₐₓ) in which the constants a1, b1 and c1 are established from tests performed on a significant range of hollow bodies used in the barrier layer deposition machines of the invention.

More generally, it has been found that the cyclic conduction ratio Th, as a percentage, is dependent on the average power setpoint P_{avg} by the polynomial equation having the formula

Th=a1*(P_{avg})ⁿ+b1*(P_{avg})ⁿ⁻¹+c1*(P_{avg})ⁿ⁻²+ . . . +k1*(P_{avg})^{n-p},

where n and p are whole numbers, n being higher than or equal to p, and (a1, b1, c1, . . . k1) being variable coefficients.

In the case in which the wave has a sinusoidal form, the maximum power Pₘₐₓ is thus calculated from the equation having the following formula

Pₘₐₓ=π*P_{avg}/2*Th).

In this way, knowing the two characteristic curves Pₘₐₓ=g(P_{avg}) and Th=G(P_{avg}), it suffices for the user to define the desired setpoint P_{avg} so as to operate the generator according to the first operating mode of the invention.

Thus, in short, the first generator operating mode comprises two alternatives in the case of the use of a sinusoidal waveform, in which either the pair of formulas (Pₘₐₓ=a*(P_{avg})²+b*P_{avg}+c; Th(%)=100*P_{avg}*Pi/(*2Pₘₐₓ)) are applied, or the pair of formulas (Th=a1*P_{avg}²+b1*P_{avg}+c1; Pₘₐₓ=π*P_{avg}/(2*Th)) are applied. The choice of the pair of formulas to be applied depends on the control parameters of the device for plasma deposition of the barrier layer (for example, the precursor gas injection rate, internal volume, etc.).

FIG. 5 shows a graph illustrating a second operating mode of the generator according to the invention (MODE 2).

The variations in maximum power Pₘₐₓ are shown as a function of the average microwave power P_{avg}. The maximum power Pₘₐₓ of the second operating mode is determined according to the desired characteristics of the containers after treatment. It is selected in the trapezoidal area bounded by the vertical lines corresponding to a minimum average power P_{avg,min} and to a maximum average power P_{avg,max}, by a horizontal line 33 corresponding to an upper bound value of the maximum power P_{max,max} not to be exceeded by the magnetron 16 and the power supply thereof, and by an inclined line 34 lying between the points (P_{avg,min}; P_{max,min}) and (P_{avg,max}; P1), the value of P_{max,min} corresponding to the value of the maximum power associated with the minimum average power P_{avg,min} and the value of P1 corresponding to the value of the lowest possible maximum power associated with a maximum average power P_{avg,max} and passing through the line 34, the equation connecting these two points being like: Pₘₐₓ=a2*P_{avg}+b2, where the coefficients a2 and b2 are determined so that P_{avg} never exceeds a limit value of the cyclic ratio Th. This limit value, which is constant regardless of the average power setpoint P_{avg}, is given by the design of the magnetron 16 and of the power supply thereof.

In a preferred operating mode, the operator enters, on means for entering maximum power values, provided on a man-machine interface, a value of Pₘₐₓ, i.e. a value P_{max,x}. The generator comprises means for producing and indicating on the man-machine interface a possible range PP′ of power setpoints P_{avg} lying within the abovementioned trapezium. The range PP′ given in FIG. 5 is associated with two limit maximum powers Pₘₐₓ, that is the maximum power varies between P_{max,min} and P_{max,max}.

In short, according to this second operating mode, a P_{max,x} is preselected, and the value of P_{avg} is then selected on the line PP′.

To implement the second operating mode, the control device of the invention comprises means for running a computation sequence, the output of said means being connected to means for indicating to an operator the possible range of use of P_{avg} as a function of the value Pₘₐₓ which he enters on a means for acquiring a numerical value. If, during step E4, the value P_{avg} is outside these limits, that is outside the trapezium shown in FIG. 5, the control device, which includes means for testing the value of the average power P_{avg} and means for inhibiting the step of excitation of a cold plasma, prohibits the passage to step E6. The control device of the invention then comprises means for indicating the status of inhibition of plasma excitation. It is then necessary either to modify the value of P_{avg}, or to reconsider the value of Pₘₐₓ to broaden the window of values P_{avg} available during step E4. For this purpose, the control device of the invention accordingly comprises means for entering a new value of the average power P_{avg} in response to the activation of the means for indicating the status of inhibition of plasma excitation and/or means for broadening the window of maximum power values Pₘₐₓ, particularly by means for entering a new value of the maximum power Pₘₐₓ.

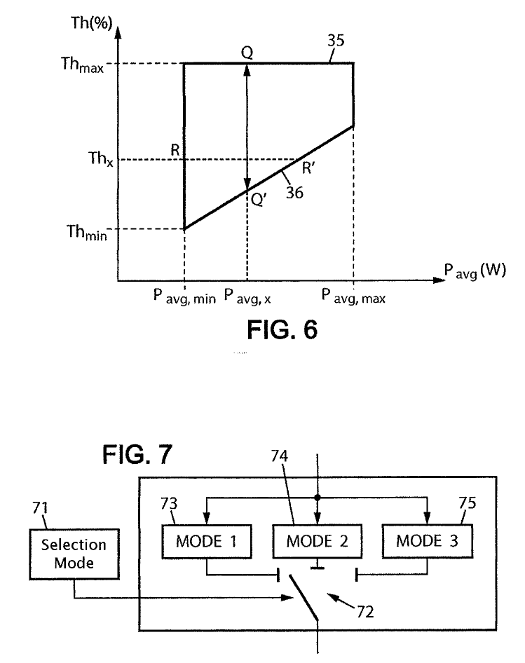

FIG. 6 shows a graph illustrating a third operating mode for obtaining the objectives defined for the hollow body and the barrier layer thereof deposited by cold plasma.

The areas of choice of the cyclic conduction ratio Th as a function of the average power setpoint P_{avg} consumed by the magnetron 16 are shown. The cyclic ratio Th in the third operating mode is determined according to the desired characteristics of the containers after treatment. It is selected in the trapezoidal area bounded by the vertical lines corresponding to a minimum average power consumption P_{avg,min} (associated with a value of the minimum cyclic ratio Thₘᵢₙ) and a maximum average power consumption P_{avg,max} by a horizontal line 35 corresponding to the value of the maximum cyclic ratio Thₘₐₓ not to be exceeded for the operating safety of the magnetron 16 and of its power supply circuit used in the barrier layer deposition machine of the invention, and by an inclined line 36 of which the equation is like Th=c*P_{avg}+d where the coefficients c and d are determined for a type of magnetron which must not exceed a maximum power Pₘₐₓ given by the characteristics of the magnetron and its power supply, with an average power P_{avg} between a minimum value P_{avg,min} and a maximum value P_{avg,max} Thus, using this trapezium shown in FIG. 6, it is possible to determine, for a given average power P_{avg,x}, the range QQ′ in which the cyclic ratio Thₓ may be varied.

Thus, in this third operating mode, once the value of Thₓ has been selected, the possible range of variation of the value P_{avg} is shown by the line RR′ in FIG. 6 corresponding to the horizontal line starting from point R having an x-axis value P_{avg,min} and a y-axis value Thₓ to the point R′ located on the line 36 and having a y-axis value Thₓ.

In short, in this third operating mode Thₓ is preselected, and P_{avg} is then selected on the line RR′.

To implement the third operating mode, the control device of the invention comprises means for running a computation sequence, the output of said means being connected to means for indicating to an operator the possible range of use of P_{avg} as a function of the value Thₓ which he enters on a means for acquiring a numerical value. If, during step E4, the value P_{avg} is outside these limits, the control device comprises and activates means for prohibiting the passage to step E6. It is then necessary either to modify the value of P_{avg}, or to reconsider the value of Th to broaden the window of values P_{avg} available during step E4. The result is that the device of the invention also comprises means for modifying the value of the cyclic conduction (or repetition) ratio Th of the waveform, means for modifying the value of the power setpoint P_{avg} and means for selecting the abovementioned first means or second means.

In FIG. 7, the inventive device also comprises a circuit for selecting operating modes represented in—-step E2, a circuit that is incorporated in the microcontroller and comprises a mode selection circuit 71 corresponding to an operating mode request. An electronic switch 72 is connected to three circuits 72, 73 and 74 each corresponding to an operating mode MODE 1 (FIG. 4), MODE 2 (FIG. 5) and MODE 3 (FIG. 6).

The present invention therefore relates, according to one of its aspects, to a device for controlling a high-voltage power generator for magnetron for the cold-plasma deposition of a barrier layer of the invention, of the type comprising:
a circuit for controlling a high-voltage power supply generator;
a circuit for controlling the control electrodes of a high-frequency power switch bridge in relation with a power waveform setpoint, said control device implementing the method of the invention and comprising:
means for storing parameters of maximum power, of conduction according to a predefined operating mode,
means for selecting an average power setpoint P_{avg},
means for determining an operating frequency, of recurrence T,
means for selecting a generator operating mode (MODE 1, MODE 2, MODE 3), and means for determining all the instantaneous setpoint parameters (peak power, frequency, recurrence frequency) defining the power wave for a work target expressed in terms of performance of the deposit created on the hollow body and the respect of the integrity thereof, while controlling the temperature rise thereof during the deposition.

According to another of its aspects, the invention relates to a machine for depositing a barrier layer on the inside wall of a plastic hollow body by means of a cold plasma which is obtained by assembling a hollow body transfer mechanism, and at least one workstation to apply a cold plasma to the hollow body or bodies which are inserted therein at each operating step of the transfer mechanism of the machine.

This treatment requires the combination at each workstation of at least one magnetron 16 and of the high-voltage generator associated thereto.

The rest of the description will recite examples of application and practical implementation of the method of the invention.

We have seen above that the method according to the invention relates to a method for controlling a high-voltage power supply generated for a magnetron 16 for producing a cold plasma inside a hollow body in order to carry out the deposition of the barrier layer inside said hollow body, the method being characterized in that it consists of selecting (step E2) a generator operating mode from a plurality of operating modes (MODE 1, MODE 2, MODE 3), the modification of the operating mode (MODE 1, MODE 2, MODE 3) of the generator varying at least one coefficient ((a, b, c,); (a1, b1, c1)) defining a maximum power Pₘₐₓ of the wave of the supply power of the magnetron 16 in relation with an average power setpoint P_{avg} of the magnetron 16, the magnetron 16 supply wave being repeated recurrently with a cyclic conduction ratio Th depending on the average power setpoint P_{avg} and/or the maximum power Pₘₐₓ.

According to a first operating mode of the inventive method, the maximum power Pₘₐₓ of the wave is predefined according to the power setpoint P_{avg}.

According to one of the alternatives for implementing this first operating mode, the equation between the average power P_{avg} and the maximum power Pₘₐₓ has the parabolic form Pₘₐₓ=a*P_{avg})²+b*P_{avg}+c, where a, b and c are variable coefficients, the cyclic conduction ratio Th being determined by the equation

Th=100*P_{avg}*π/(2*P_{max).}

In general, and regardless of the generator operating mode, the coefficient a is between (−0.002) and 0.002, the coefficient b is between 0 and 4, and the coefficient c is between 0 and 3000.

More precisely, for the first generator operating mode, a=(−0.0012), b=3.22 and c=247.6.

Thus, for an average power P_{avg} of 350 W, the maximum power Pₘₐₓ is about 1230 W and the cyclic ratio calculated is about 45%.

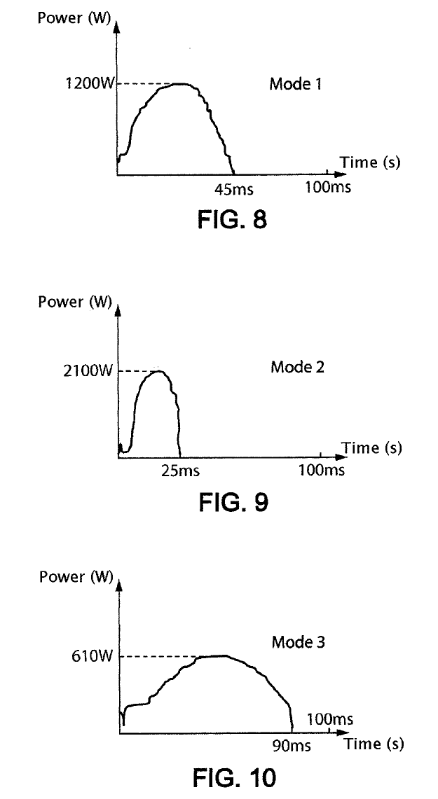

FIG. 8 thus illustrates a representation of the waveform obtained from these setting parameters for the first generator operating mode.

Alternatively, it is also possible to set a generator operating mode with the cyclic conduction ratio Th which is dependent on the average power setpoint P_{avg} by the equation having the formula

Th(%)=a1(P_{avg})²+b1*P_{avg})+c1

where a1, b1, c1 are variable coefficients, the maximum power Pₘₐₓ then being determined by the equation Pₘₐₓ=π*P_{avg}/(2*Th). The coefficients a1, b1 and c1 thus also define a relation between the maximum power Pₘₐₓ and the average power P_{avg}.

By way of example, the values of a1 may be between (−10⁻⁷) and (−10⁻⁴), the values of b1 may be between 0.03 and 0.06, the values of c1 may be between 25 and 30. Preferably, a1 is (−5*10⁻⁶), b1 is 0.0529, and c1 is 27.85.

Preferably, in an operating mode, for example MODE 1, none of the coefficients ((a, b, c); (a1, b1, c1)) is zero.

In another operating mode (MODE 2, MODE 3) of the generator, at least two coefficients a, b and c are zero.

More precisely, in a second operating mode (MODE 2), the maximum power Pₘₐₓ is fixed constant, preferably at the value of 2100 W with an upper limit value of the cyclic ratio Thₘₐₓ of 90%.

According to this second operating mode, the values of the coefficients a and b are zero and the value of c is therefore 2100.

A cyclic ratio Th is thereby obtained that is linearly dependent on the average power P_{avg}, preferably in the case in which the wave is of a sinusoidal type, Th is about 0.07 P_{avg}. The value of Th is calculated by the equation Th(%)=100*P_{avg}*π/(2*Pₘₐₓ), in the case in which the wave is of a sinusoidal type.

Thus, for an average power P_{avg} of 350 W, the maximum power Pₘₐₓ is 2100 W and the cyclic ratio Th is 25%, and the waveform such as shown in FIG. 9 is obtained.

It has been described above and illustrated in FIG. 5 that, according to this second embodiment, the maximum power Pₘₐₓ is determined and variable on the basis of a safe area bounded by a maximum permissible value of the maximum power P_{max,max} for the magnetron 16 and a lower maximum power value P_{max,min} determined by a maximum cyclic conduction ratio Thₘₐₓ given by the design of the magnetron 16 and of the power supply thereof.

According to a third generator operating mode, the maximum power Pₘₐₓ is linearly dependent on the value of the average power setpoint P_{avg}.

In this case, the coefficients a and c are zero and, preferably, the value of b is set at 1.745, hence Pₘₐₓ=1.745 P_{avg}.

According to this third embodiment, the cyclic conduction ratio Th is fixed, and preferably fixed at 90%.

Thus, for an average power P_{avg} of 350 W, the maximum power Pₘₐₓ is 610 W and the waveform obtained is such as shown in FIG. 10.

It has been described above and illustrated in FIG. 6 that, according to this third embodiment, the cyclic conduction ratio Th of the waveform is determined and variable on the basis of a safe surface bounded by a value of the maximum permissible cyclic conduction ratio Thₘₐₓ and a lower value of the maximum cyclic conduction ratio Thₘᵢₙ, determined as a function of the upper bound of the maximum permissible power P_{max,max}, which depends on the characteristics of the magnetron 16 and its power supply.

In general, the coefficients ((a, b, c); (a1, b1 c1)) are determined by treatment tests on a batch of hollow bodies, from which the optimal equation between the average power setpoint P_{avg}, the maximum power Pₘₐₓ and the cyclic conduction ratio Th is derived.

In order to test the leak tightness of the internal barrier layer formed with the various generator control modes, comparative tests were conducted on the three modes by injecting an acetylene gas C₂H₂ into the internal volume of a hollow body, such as a bottle, placed in a cavity. In fact, the device for the deposition of a barrier layer by the formation of a plasma consists of a cylindrical-shaped metal cavity, in which the hollow body can be placed, and of a microwave waveguide containing a microwave antenna connected to the power generator, this cavity itself being connected to a vacuum system and a system for injecting gases, such as acetylene. The setting parameters are an average power P_{avg} of between 200 W and 450 W, a flow rate of acetylene gas, injected into the internal volume of the hollow body, of between 60 sccm and 160 sccm (standard cubic centimeters per minute) and a deposition time of between 1.2 and 4 seconds. The other parameters, such as the deposition pressure and the pulse frequency, are kept constant.

In each of the following examples, a batch of five bottles was tested for each of the three operating modes, the obtained values of the permeability to oxygen being measured using an Ox-Tran (registered trademark) measurement system, supplying values in cc/bottle/24 h.

The bottles used were PET bottles with a capacity of 520 ml and a weight of 28 g, knowing that the value of the permeability of a PET bottle without coating is 0.04 cc/bottle/24 h.

### Example No. 1

The setting parameters are the following:
Acetylene flow rate 160 sccm
Average power setpoint 350 W
Deposition time 1.4 s
Pulse frequency 100 Hz

| | Generator operating mode | | |
|---|---|---|---|
| | Mode 1 | Mode 2 | Mode 3 |
| Average permeability | 0.0029 | 0.0021 | 0.0110 |
| BIF (Barrier | 13.7 | 19 | 3.6 |
| Improvement Factor), | | | |
| ratio of the | | | |
| permeability values of | | | |
| an untreated bottle to | | | |
| a treated bottle | | | |

It may be observed that according to these setting parameters, the barrier improvement factors (BIF) are the best for modes 1 and 2.

### Example No. 2

The setting parameters are the following:
Acetylene flow rate 60 sccm
Average power setpoint 200 W
Deposition time 4 s
Pulse frequency 100 Hz

| | Generator operating mode | | |
|---|---|---|---|
| | Mode 1 | Mode 2 | Mode 3 |
| Average permeability | 0.0043 | 0.0037 | 0.0171 |
| BIF (Barrier | 9.3 | 10.8 | 2.3 |
| Improvement Factor), | | | |
| ratio of the | | | |
| permeability values of | | | |
| an untreated bottle to | | | |
| a treated bottle | | | |

It may also be observed that according to these setting parameters, the barrier improvement factors (BIF) are the best for modes 1 and 2.

### Example No. 3

The setting parameters are the following:
Acetylene flow rate 120 sccm
Average power setpoint 210 W
Deposition time 1.4 s
Pulse frequency 100 Hz

| | Generator operating mode | | |
|---|---|---|---|
| | Mode 1 | Mode 2 | Mode 3 |
| Average permeability | 0.0141 | 0.0044 | 0.0231 |
| BIF (Barrier | 2.8 | 9.1 | 1.7 |
| Improvement Factor), | | | |
| ratio of the | | | |
| permeability values of | | | |
| an untreated bottle to | | | |
| a treated bottle | | | |

It may be observed that, according to these setting parameters, the barrier improvement factor (BIF) is the best for mode 2.

Similarly, the efficiency of the three operating modes of the generator according to the invention for the deposition of an internal barrier layer was tested by the successive deposition of two different layers, with a first deposition produced by the injection, into the internal volume of the hollow body, of a gas mixture of HMDSO (hexamethyldisiloxane) and nitrogen N₂, and a second, deposition produced by the injection, into the internal volume of the hollow body, of a gas mixture of HMDSO, nitrogen gas N₂ and oxygen O₂.

The variable parameters tested concern the average power P_{avg} varying between 200 W and 450 W, the flow rate of HMDSO gas varying from 4 to 20 sccm, the nitrogen flow rate varying from 10 to 100 sccm, the oxygen flow rate varying from 40 to 200 sccm seconds, the deposition time for the first layer varying between 0.5 and 2 seconds, and the deposition time for the second layer varying between 2 to 4 seconds.

The bottles had the same characteristics as previously, that is a volume of 520 ml and a weight of 28 g. The values of permeability to oxygen obtained were measured using an Ox-Tran (registered trademark) measurement system, supplying values in cc/bottle/24 h, knowing that the value of the permeability of an uncoated PET bottle is 0.04 cc/bottle/24 h.

Three examples of comparative tests will be shown below for the three operating modes of such a two-layer barrier layer deposition with a step 1 for the deposition of the first layer and a step 2 for the deposition of the second layer.

### Example 4

### Operating Conditions

| | Step 1 | Step 2 |
|---|---|---|
| HMDSO flow rate (sccm) | 6 | 6 |
| Oxygen flow rate (sccm) | 0 | 60 |
| Nitrogen flow rate (sccm) | 62 | 62 |
| Average power P_{avg} (W) | 350 | 350 |
| Deposition time (s) | 0.5 | 2.5 |

The results obtained are given in the table below

| | Generator operating mode | | |
|---|---|---|---|
| | Mode 1 | Mode 2 | Mode 3 |
| Average permeability | 0.0080 | 0.0112 | 0.0078 |
| BIF (Barrier | 5 | 3.6 | 5.1 |
| Improvement Factor), | | | |
| ratio of the | | | |
| permeability values of | | | |
| an untreated bottle to | | | |
| a treated bottle | | | |

### Example 5

### Operating Conditions (with an Average Power P_{avg} Lower than the Average Power P_{avg} Compared to the Operating Conditions of Example 4)

| | Step 1 | Step 2 |
|---|---|---|
| HMDSO flow rate (sccm) | 6 | 6 |
| Oxygen flow rate (sccm) | 0 | 60 |
| Nitrogen flow rate (sccm) | 62 | 62 |
| Average power P_{avg} (W) | 250 | 250 |
| Deposition time (s) | 0.5 | 2.5 |

The results obtained are given in the table below

| | Generator operating mode | | |
|---|---|---|---|
| | Mode 1 | Mode 2 | Mode 3 |
| Average permeability | 0.0080 | 0.0099 | 0.0091 |
| BIF (Barrier | 5 | 4 | 4.4 |
| Improvement Factor), | | | |
| ratio of the | | | |
| permeability values of | | | |
| an untreated bottle to | | | |
| a treated bottle | | | |

### Example 6

### Operating Conditions (with a Decrease of the Average Power P_{avg} Only for Step 1 in Comparison with the Operating Conditions of Example 4)

| | Step 1 | Step 2 |
|---|---|---|
| HMDSO flow rate (sccm) | 6 | 6 |
| Oxygen flow rate (sccm) | 0 | 60 |
| Nitrogen flow rate (sccm) | 62 | 62 |
| Average power P_{avg} (W) | 250 | 350 |
| Deposition time (s) | 0.5 | 2.5 |

The results obtained are given in the table below

| | Generator operating mode | | |
|---|---|---|---|
| | Mode 1 | Mode 2 | Mode 3 |
| Average permeability | 0.0069 | 0.0069 | 0.0081 |
| BIF (Barrier | 5.8 | 5.8 | 4.9 |
| Improvement Factor), | | | |
| ratio of the | | | |
| permeability values of | | | |
| an untreated bottle to | | | |
| a treated bottle | | | |

It may thus be observed that in examples 4 to 6, the three operating modes are approximately equivalent, even though mode 2 is less satisfactory in terms of BIF in example 4 and mode 3 in example 6.
It is thus possible according to the method in accordance with the invention to rapidly and simply select the characteristic parameters of an optimal wave for the formation of an internal barrier layer in a hollow body and varying the variable coefficients relating the maximum power Pₘₐₓ, the average power P_{avg} and the cyclic recurrence ratio Th.

1-20. (canceled)

21. A method for controlling a high-voltage power supply generator for a magnetron for producing a cold plasma inside a hollow body in order to carry out the deposition of a barrier layer within said hollow body, wherein it consists in selecting a generator operating mode from a plurality of operating modes, a modification of the operating mode of the generator varying at least one coefficient defining a maximum power Pₘₐₓ of the waveform of the supply power of the magnetron in relation with an average power setpoint P_{avg} of the magnetron, the magnetron supply waveform being repeated recurrently with a cyclic conduction ratio Th depending on the average power setpoint P_{avg} and/or the maximum power Pₘₐₓ.

22. The method as claimed in claim 21, wherein the maximum power Pₘₐₓ of the waveform is predetermined in relation with the power setpoint P_{avg}.

23. The method as claimed in claim 21, wherein said relation between the average power P_{avg} and the maximum power Pₘₐₓ has the polynomial form
Pₘₐₓ=a*(P_{avg})ⁿ+b*(P_{avg})ⁿ⁻¹+c*(P_{avg})ⁿ⁻²+ . . . +k*(P_{avg})^{n-p}
where n and p are whole numbers, n being higher than or equal to p, and a, b, c, . . . k being variable coefficients.

24. The method as claimed in claim 23, wherein said polynomial equation has the parabolic form Pₘₐₓ=a*(P_{avg})²+b*P_{avg}+c where a, b, c are variable coefficients.

25. The method as claimed in claim 23, wherein the cyclic conduction ratio Th, in percent, is determined by the equation
Th=100*P_{avg}*π/(2*P_{max).}

26. The method as claimed in claim 21, wherein the cyclic conduction ratio Th, in percent, is dependent on the average power setpoint P_{avg} via the polynomial equation having the formula
Th=a1*(P_{avg})ⁿ+b1*(P_{avg})ⁿ⁻¹+c1*(P_{avg})ⁿ⁻²+ . . . +k1*(P_{avg})^{n-p}
where n and p are whole numbers, n being higher than or equal to p, and a1, b1, c1, . . . , k1 being variable coefficients.

27. The method as claimed in the claim 26, wherein said polynomial equation has the parabolic form Th=a1(P_{avg})²+b1*P_{avg}+c1, where a1, b1, c1 are variable coefficients.

28. The method as claimed in claim 26, wherein the maximum power Pₘₐₓ is determined by the equation Pₘₐₓ=π*P_{avg}/(2*Th).

29. The method as claimed in claim 23, wherein, in an operating mode, none of the coefficients a, b, c; a1, b1, c1 is zero.

30. The method as claimed in claim 23, wherein, in an operating mode, at least two coefficients a, b, c; a1, b1, c1 are zero.

31. The method as claimed in claim 21, wherein, in an operating mode, the maximum power Pₘₐₓ is fixed constant.

32. The method as claimed in claim 31, wherein the cyclic ratio Th is linearly dependent on the average power P_{avg}.

33. The method as claimed in claim 30, wherein the maximum power is determined and variable on the basis of a safe area bounded by a maximum permissible value of the maximum power P_{max,max} for the magnetron and a lower value of the maximum power P_{max,min} determined by a maximum cyclic conduction ratio Thₘₐₓ given by the design of the magnetron and of the power supply thereof.

34. The method as claimed in claim 21, wherein, in an operating mode, the maximum power Pₘₐₓ is linearly dependent on the value of the average power setpoint P_{avg}.

35. The method as claimed in claim 34, wherein the cyclic conduction ratio Th is fixed.

36. The method as claimed in claim 30, wherein the cyclic conduction ratio Th of the waveform is determined and selectable on the basis of a safe area bounded by a value of the maximum permissible cyclic conduction ratio Thₘₐₓ and a lower value of the minimum cyclic conduction ratio Thₘᵢₙ determined according to the upper limit of the maximum permissible power P_{max,max} which depends on the characteristics of the magnetron and of the power supply thereof.

37. The method as claimed in claim 34, wherein the cyclic conduction ratio Th of the waveform is determined and selectable on the basis of a safe area bounded by a value of the maximum permissible cyclic conduction ratio Thₘₐₓ and a lower value of the minimum cyclic conduction ratio Thₘᵢₙ determined according to the upper limit of the maximum permissible power P_{max,max} which depends on the characteristics of the magnetron and of the power supply thereof.

38. The method as claimed in claim 35, wherein the cyclic conduction ratio Th of the waveform is determined and selectable on the basis of a safe area bounded by a value of the maximum permissible cyclic conduction ratio Thₘₐₓ and a lower value of the minimum cyclic conduction ratio Thₘᵢₙ determined according to the upper limit of the maximum permissible power P_{max,max} which depends on the characteristics of the magnetron and of the power supply thereof.

39. The method as claimed in claim 23, wherein said coefficients a, b, c; a1, b1, c1 are determined by treatment tests of a batch of hollow bodies from which a relation is derived between the average power setpoint P_{avg}, the maximum power Pₘₐₓ and the cyclic conduction ratio Th.

40. The method as claimed in claim 23, wherein the coefficient a is between (−0.0020) and 0.0020, in that the coefficient b is between 0 and 4, and in that the coefficient c is between 0 and 3000.

41. A device for controlling a high-voltage power supply generator for magnetron for the cold-plasma deposition of a barrier layer of the invention, of the type comprising:
a circuit for controlling a high-voltage power supply generator;
a circuit for controlling the control electrodes of a power switch bridge in relation with a power waveform setpoint, said control device using the method as claimed in claim 41 and comprising:
means for storing parameters of maximum power, of conduction in relation with a predefined operating mode,
means for selecting an average power setpoint P_{avg},
means for determining an operating frequency,
means for selecting a generator operating mode, and
means for determining all the instantaneous setpoint characteristics defining the power wave for a work target expressed in terms of performance of the deposit created on the hollow body and the respect of the integrity thereof, while controlling its temperature rise during the deposition.

42. A machine for depositing a barrier layer on the inside wall of a plastic hollow body, such as a bottle, using a cold plasma excited by a magnetron, supplied by a high-voltage generator, controlled by a control device as claimed in claim 41.
